(19) United States
(12) Patent Application Publication
(10) Pub. No.: US 2025/0278998 A1
(43) Pub. Date: Sep. 4, 2025

(54) INFORMATION PROCESSING SYSTEM, INFORMATION PROCESSING METHOD, AND NON-TRANSITORY COMPUTER READABLE STORAGE MEDIUM STORING INFORMATION PROCESSING PROGRAM

(71) Applicant: TOYOTA JIDOSHA KABUSHIKI KAISHA, Toyota-shi (JP)

(72) Inventors: Masataka OKUDA, Toyota-shi (JP); Kanade KURIYAMA, Toyota-shi (JP); Masatoshi KAKUTANI, Miyoshi-shi (JP); Kaoru YOSHIDA, Nisshin-shi (JP); Toshiki SHINOHARA, Toyota-shi (JP)

(73) Assignee: TOYOTA JIDOSHA KABUSHIKI KAISHA, Toyota-shi (JP)

(21) Appl. No.: 19/034,811

(22) Filed: Jan. 23, 2025

(30) Foreign Application Priority Data
Feb. 29, 2024 (JP) 2024-030138

(51) Int. Cl. G08G 1/01; G08G 1/052

(52) U.S. Cl. CPC G08G 1/0145; G08G 1/052

(57) ABSTRACT

An information processing system acquires moving body information that indicates a position of each of multiple moving bodies existing in the real world. The information processing system acquires, based on the moving body information, predictive moving body information at a prescribed cycle. The predictive moving body information indicates a predictive position of each of the multiple moving bodies after a point in time at which the moving body information is acquired. The information processing system is configured to set the cycle for acquiring the predictive moving body information in at least one zone among multiple zones in which the moving bodies are present to be longer than the cycle for acquiring the predictive moving body information in the other zones.

### CROSS-REFERENCE TO RELATED APPLICATIONS

This application is based upon and claims the benefit of priority from Japanese Patent Application No. 2024-030138, filed on Feb. 29, 2024, the entire contents of which are incorporated herein by reference.

### BACKGROUND

### 1. Field

The present disclosure relates to an information processing system, an information processing method, and a non-transitory computer readable storage medium storing an information processing program for reproducing a real-world traffic environment in a virtual space.

### 2. Description of Related Art

Digital twin technology enables the reproduction of real-world environments within a virtual space. Japanese Laid-Open Patent Publication No. 2020-013557 discloses a system that utilizes a traffic digital twin to reproduce a real-world traffic environment in a virtual space.

To accurately replicate the real-world positions of multiple moving bodies in a virtual space, one approach is to minimize the update cycle for the positions of the moving bodies in the virtual world. However, this approach significantly increases the processing load on the device responsible for updating the positions of multiple moving bodies.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a first general aspect, an information processing system includes processing circuitry. The processing circuitry is configured to acquire moving body information that indicates a position of each of multiple moving bodies existing in the real world, and acquire, based on the moving body information, predictive moving body information at a prescribed cycle. The predictive moving body information indicates a predictive position of each of the multiple moving bodies after a point in time at which the moving body information is acquired. The processing circuitry is also configured to set the cycle for acquiring the predictive moving body information in at least one zone among multiple zones in which the moving bodies are present to be longer than the cycle for acquiring the predictive moving body information in the other zones.

In a second general aspect, an information processing method includes: acquiring moving body information that indicates a position of each of multiple moving bodies existing in the real world; acquiring, based on the moving body information, predictive moving body information at a prescribed cycle, the predictive moving body information indicating a predictive position of each of the multiple moving bodies after a point in time at which the moving body information is acquired; and setting the cycle for acquiring the predictive moving body information in at least one zone among multiple zones in which the moving bodies are present to be longer than the cycle for acquiring the predictive moving body information in the other zones.

In a third general aspect, a non-transitory computer readable storage medium stores an information processing program to be executed by processing circuitry included in an information processing system. The information processing program causes the processing circuitry to set a cycle for acquiring predictive moving body information in at least one zone among multiple zones in which the moving bodies are present to be longer than the cycle for acquiring the predictive moving body information in the other zones. The predictive moving body information is acquired based on moving body information that indicates a position of each of multiple moving bodies present in the real world. The predictive moving body information indicates a predictive position of each of the multiple moving bodies after a point in time at which the moving body information is acquired.

Other features and aspects will be apparent from the following detailed description, the drawings, and the claims.

### BRIEF DESCRIPTION OF THE DRAWINGS

FIG. 1 is a schematic diagram illustrating an information processing system according to an embodiment.

FIG. 2 is a schematic diagram illustrating a processing device, a communication device, and a storage device included in the information processing system shown in FIG. 1.

FIG. 3 is a schematic diagram showing a manner in which the information processing system shown in FIG. 1 acquires predictive moving body information.

FIG. 4 is a flowchart showing a flow of processes executed by the information processing system shown in FIG. 1.

FIG. 5 is a schematic diagram illustrating an example of an update field for which the information processing system shown in FIG. 1 updates predictive moving body information.

FIG. 6 is a table showing a relationship between moving speeds of the moving bodies shown in FIG. 5, update cycle labels, and update cycles of predictive moving body information.

FIG. 7 is a table showing moving speeds, zones, and update cycles of the respective moving bodies in the update field shown in FIG. 5.

FIG. 8 is a table showing a manner in which the processing device included in the information processing system shown in FIG. 1 adjusts update cycles.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

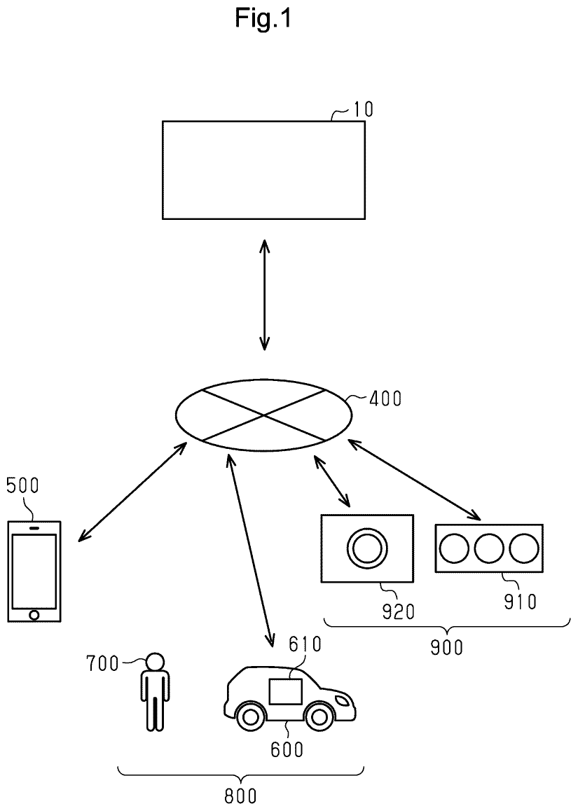

An information processing system 10 according to an embodiment will now be described with reference to FIGS. 1 to 8.

### Overview of Information Processing System 10

The information processing system 10 acquires moving body information, which is information indicating the position and behavior of each of multiple moving bodies 800 in the real world, at multiple points in time. The moving bodies 800 include vehicles 600, pedestrians 700, bicycles, and animals. Vehicles 600 include two-wheeled vehicles.

The information processing system 10 calculates, using the acquired moving body information, predictive moving body information indicating the predictive position of each moving body 800 after the point in time at which the moving body information is acquired, at a prescribed update cycle. The predictive moving body information is obtained by reproducing a real-world traffic environment in a virtual space.

As shown in FIG. 1, the information processing system 10 is configured to communicate, via an external communication network 400, with multiple information processing terminals 500 (only one is shown), multiple vehicles 600 (only one is shown), and multiple roadside sensors 900.

The information processing terminal 500 shown in FIG. 1 collects the location information of a pedestrian 700 carrying an information processing terminal 500 as moving body information. The location information is coordinate values of latitude and longitude. The information processing terminal 500 transmits the collected location information of the pedestrian 700 to the information processing system 10 via the external communication network 400. The information processing terminal 500 is, for example, a smartphone or the like carried by the pedestrian 700. The information processing terminal 500 may be a wearable terminal, a tablet terminal, or the like. Examples of the wearable terminal include a bracelet-type terminal worn on the wrist and a necklace-type terminal worn on the neck.

The vehicle 600 shown in FIG. 1 is equipped with vehicle on-board sensors 610. The vehicle 600 transmits the moving body information collected by the vehicle on-board sensors 610 to the information processing system 10 via the external communication network 400. The vehicle on-board sensors 610 include, for example, a vehicle speed sensor, an accelerator sensor, a brake sensor, a steering sensor, and an acceleration sensor. The acceleration sensor is, for example, an inertial measurement unit (IMU).

The vehicle 600 includes an external camera, a sonar sensor, and a location information acquisition system as the vehicle on-board sensors 610. The external camera and the sonar sensor mounted on the vehicle 600 collect information on distances between the vehicle 600 and other objects located around the vehicle 600 to generate observation data. The vehicle 600 may include a light detection and ranging (LiDAR) sensor as a sensor that serves a role similar to that of an external camera and a sonar sensor. The location information acquisition system is, for example, a global navigation satellite system (GNSS), a real time kinematic (RTK) system, a LiDAR sensor, or the like.

The vehicle on-board sensors 610 collect moving body information, including vehicle information such as a vehicle identification number (VIN) of the vehicle 600 and information on a vehicle speed, a traveling direction, and a traveling trajectory and a position of the vehicle 600, for example.

The roadside sensors 900 shown in FIG. 1 are multiple sensors installed on the road. The roadside sensors 900 include multiple traffic lights 910, multiple roadside cameras 920, and LiDAR sensors. Each traffic light 910 transmits information related to changes in the state of the traffic infrastructure, such as the timing at which the traffic light 910 turns green and the time during which the traffic light 910 remains green, to the information processing system 10 via the external communication network 400.

Each roadside camera 920 collects observation data around the roadside camera 920. The observation data includes moving body information of multiple moving bodies 800 around each roadside camera 920. The roadside cameras 920 include, for example, visible light cameras and infrared cameras. The LiDAR sensors installed on the road acquire point cloud data, arranged in chronological order, that is continuously observed at fixed time intervals. Each LiDAR sensor collects the moving body information of moving bodies 800 located around the LiDAR sensor.

### Configuration of Information Processing System 10

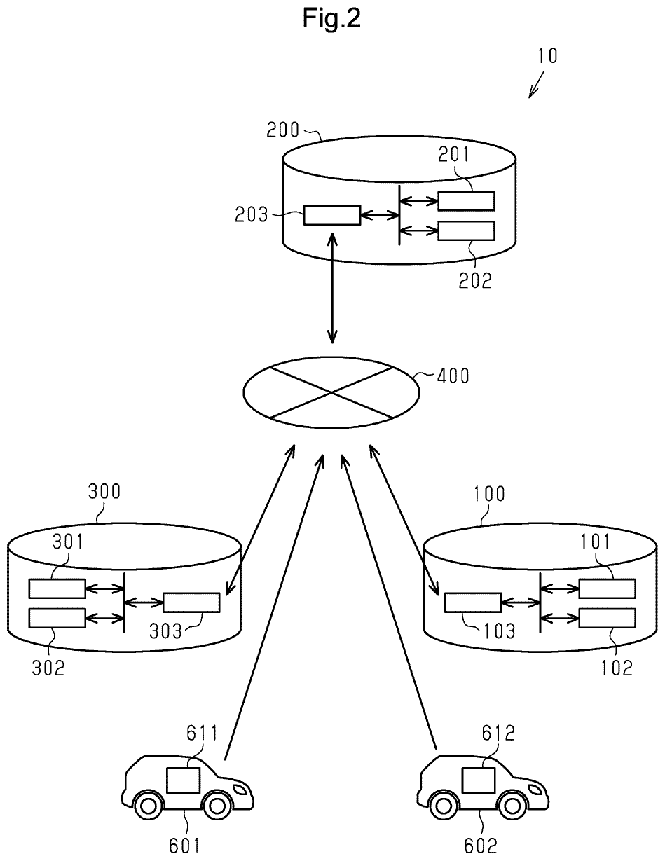

As illustrated in FIG. 2, the information processing system 10 includes a processing device 100, a storage device 200, and a communication device 300.

The processing device 100 includes first processing circuitry 101, first storage circuitry 102, and first communication circuitry 103. Programs are stored in the first storage circuitry 102. The first processing circuitry 101 executes programs stored in the first storage circuitry 102 to execute various kinds of processes. The first processing circuitry 101 includes a processor. The processing device 100 is connected to the external communication network 400 via the first communication circuitry 103.

The storage device 200 includes second processing circuitry 201, second storage circuitry 202, and second communication circuitry 203. Programs are stored in the second storage circuitry 202. The second processing circuitry 201 executes programs stored in the second storage circuitry 202 to execute various kinds of processes. The second processing circuitry 201 includes a processor. The storage device 200 is connected to the external communication network 400 via the second communication circuitry 203.

The communication device 300 includes third processing circuitry 301, third storage circuitry 302, and third communication circuitry 303. Programs are stored in the third storage circuitry 302. The third processing circuitry 301 executes programs stored in the third storage circuitry 302 to execute various kinds of processes. The third processing circuitry 301 includes a processor. The communication device 300 is connected to the external communication network 400 via the third communication circuitry 303.

Each of the processing device 100, the storage device 200, and the communication device 300 includes processing circuitry including one or more processors that execute various processes in accordance with a computer program (software). Each of the processing device 100, the storage device 200, and the communication device 300 may include processing circuitry including one or more dedicated hardware circuits such as an application-specific integrated circuit (ASIC) that executes at least a part of various processes. Alternatively, each of the processing device 100, the storage device 200, and the communication device 300 may include processing circuitry including a combination of one or more processors and one or more dedicated hardware circuits. Each processor includes a CPU and a memory module, such as a RAM and a ROM, and the memory module stores program codes or instructions configured to cause the CPU to execute processes. The memory module, which is a non-transitory computer-readable storage medium, includes any type of media that are accessible by general-purpose computers and dedicated computers.

The configuration of the information processing system 10 is not limited to the configuration illustrated in FIG. 2. For example, the processing device 100, the storage device 200, and the communication device 300 may be included in a single server. For example, the processing device 100, the storage device 200, and the communication device 300 may be connected to each other via wired connections in a manner that allows mutual communication.

FIG. 2 illustrates a first vehicle 601 and a second vehicle 602 as examples of the moving bodies 800 for which the information processing system 10 calculates the predictive moving body information. The first vehicle 601 includes a first vehicle on-board sensor 611. The first vehicle on-board sensor 611 transmits the moving body information of the first vehicle 601 to the information processing system 10 via the external communication network 400. The second vehicle 602 includes a second vehicle on-board sensor 612. The second vehicle on-board sensor transmits the moving body information of the second vehicle 602 to the information processing system 10 via the external communication network 400.

The communication device 300 acquires the moving body information transmitted from sensors at a prescribed acquisition cycle via the third communication circuitry 303. The communication device 300 stores the acquired moving body information in the third storage circuitry 302. The third processing circuitry 301 of the communication device 300 transmits the moving body information stored in the third storage circuitry 302 to the processing device 100 via the third communication circuitry 303.

The processing device 100 acquires the moving body information from the communication device 300 via the first communication circuitry 103. The processing device 100 stores the received moving body information in the first storage circuitry 102. The first processing circuitry 101 of the processing device 100 calculates predictive moving body information using the moving body information. The processing device 100 transmits the predictive moving body information to the storage device 200 via the first communication circuitry 103.

The storage device 200 receives the predictive moving body information via the second communication circuitry 203. The storage device 200 stores the acquired predictive moving body information in the second storage circuitry 202. The second processing circuitry 201 of the storage device 200 provides the predictive moving body information stored in the second storage circuitry 202 in response to a request via the external communication network 400.

The first vehicle 601 and the second vehicle 602 are examples of the moving bodies 800 for which the information processing system 10 calculates predictive moving body information. For example, the information processing system 10 calculates the predictive moving body information of the first vehicle 601 based on the moving body information acquired from the first vehicle on-board sensor 611. For example, the information processing system 10 calculates the predictive moving body information of the second vehicle 602 based on the moving body information acquired from the second vehicle on-board sensor 612.

### Calculation of Predictive Moving Body Information by Information Processing System 10

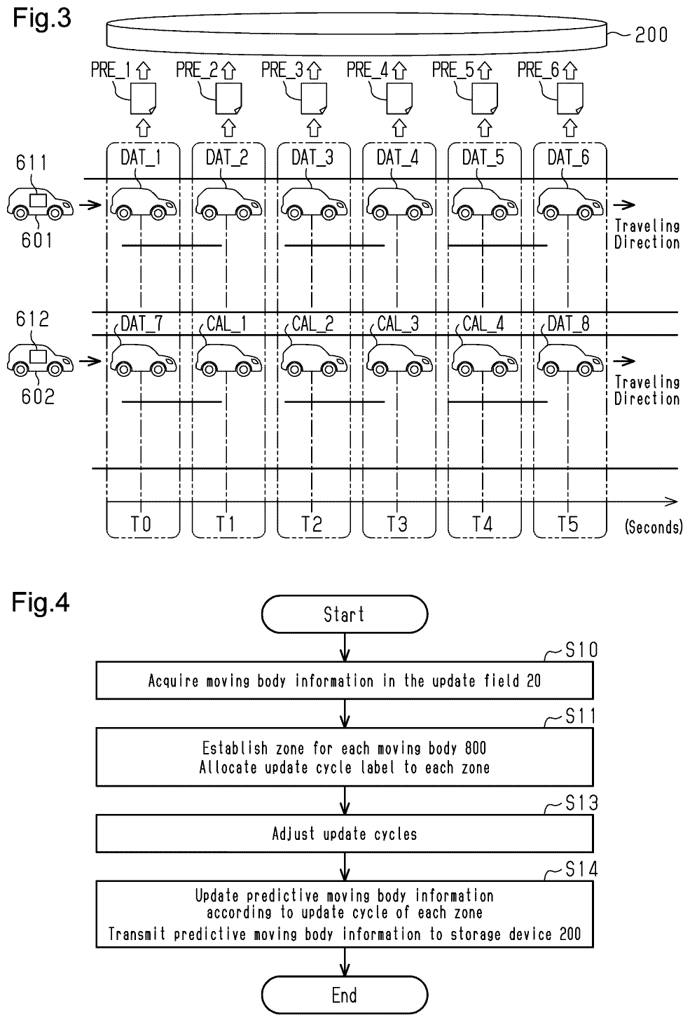

A manner in which the information processing system 10 calculates predictive moving body information will now be described with reference to FIG. 3. The communication device 300 of the information processing system 10 acquires the moving body information of each moving body 800 at the prescribed acquisition cycle. For example, the communication device 300 of the information processing system 10 acquires the moving body information of the first vehicle 601 from the first vehicle on-board sensor 611 of the first vehicle 601 every 0.1 seconds. In other words, the communication device 300 acquires the moving body information of the first vehicle 601 from the first vehicle on-board sensor 611 at an acquisition cycle of 0.1 seconds.

In FIG. 3, the moving body information of the first vehicle 601 acquired by the communication device 300 at the acquisition cycle of 0.1 seconds is represented as first moving body information DAT_1, second moving body information DAT_2, third moving body information DAT_3, fourth moving body information DAT_4, fifth moving body information DAT_5, and sixth moving body information DAT_6. The first moving body information DAT_1 is the moving body information of the first vehicle 601 acquired at a point in time T0. The second moving body information DAT_2 is the moving body information of the first vehicle 601 acquired at a point in time T1, which is 0.1 seconds after the point in time T0. The third moving body information DAT_3 is the moving body information of the first vehicle 601 acquired at a point in time T2, which is 0.1 seconds after the point in time T1. The fourth moving body information DAT_4 is the moving body information of the first vehicle 601 acquired at a point in time T3, which is 0.1 seconds after the point in time T2. The fifth moving body information DAT_5 is the moving body information of the first vehicle 601 acquired at a point in time T4, which is 0.1 seconds after the point in time T3. The sixth moving body information DAT_6 is the moving body information of the first vehicle 601 acquired at a point in time T5, which is 0.1 seconds after the point in time T4.

The acquisition cycle does not need to be a common cycle across the multiple moving bodies 800. For example, the communication device 300 acquires the moving body information of the second vehicle 602 from the second vehicle on-board sensor 612 of the second vehicle 602 every 0.5 seconds. In other words, the communication device 300 acquires the moving body information of the second vehicle 602 from the second vehicle on-board sensor 612 at an acquisition cycle of 0.5 seconds.

In FIG. 3, the moving body information of the second vehicle 602 acquired by the communication device 300 at the acquisition cycle of 0.5 seconds is shown as seventh moving body information DAT_7 and eighth moving body information DAT_8. The seventh moving body information DAT_7 is moving body information of the second vehicle 602 acquired at the point in time T0. The eighth moving body information DAT_8 is moving body information of the second vehicle 602 acquired at the point in time T5, which is 0.5 seconds after the point in time T0.

The third storage circuitry 302 of the communication device 300 shown in FIG. 2 stores the acquired moving body information. The communication device 300 transmits the moving body information stored in the third storage circuitry 302 to the processing device 100 via the third communication circuitry 303.

When acquiring the moving body information from the communication device 300 via the first communication circuitry 103, the processing device 100 updates the predictive moving body information of the first vehicle 601 and the second vehicle 602 every 0.1 seconds based on the acquired moving body information. First predictive moving body information PRE_1, second predictive moving body information PRE_2, third predictive moving body information PRE_3, fourth predictive moving body information PRE_4, fifth predictive moving body information PRE_5, and sixth predictive moving body information PRE_6 shown in FIG. 3 are predictive moving body information of the first vehicle 601 and the second vehicle 602 updated every 0.1 seconds.

The processing device 100 transmits the updated predictive moving body information to the storage device 200 via the first communication circuitry 103. When acquiring the predictive moving body information via the second communication circuitry 203, the storage device 200 stores the acquired predictive moving body information in the second storage circuitry 202.

When the information processing system 10 does not determine an appropriate update cycle of the predictive moving body information for each of the moving bodies 800, the update cycle of the predictive moving body information and the acquisition cycle of the moving body information can be different from each other. When the update cycle of the predictive moving body information is different from the acquisition cycle of the moving body information, the processing device 100 needs to calculate calculation data CAL, which is the location information of the moving body 800 at a time when no moving body information of the moving body 800 is available, based on the moving body information of the moving body 800.

As shown in FIG. 3, when the communication device 300 acquires the moving body information of the second vehicle 602 at the point in time T0, the next point in time at which the communication device 300 acquires the moving body information of the second vehicle 602 is the point in time T5, which is 0.5 seconds later. Therefore, the processing device 100 calculates the calculation data CAL, which represents the location information of the second vehicle 602 at a time when no moving body information of the second vehicle 602 is available, based on the moving body information of the second vehicle 602.

As shown in FIG. 3, the processing device 100 calculates first calculation data CAL_1, which is the location information of the second vehicle 602 at the point in time T0, based on the seventh moving body information DAT_7 of the second vehicle 602 at the point in time T1 stored in the first storage circuitry 102. The processing device 100 calculates second calculation data CAL_2, which is the location information of the second vehicle 602 at the point in time T2, based on the seventh moving body information DAT_7. The processing device 100 calculates third calculation data CAL_3, which is the location information of the second vehicle 602 at the point in time T3, based on the seventh moving body information DAT_7. The processing device 100 calculates fourth calculation data CAL_4, which is the location information of the second vehicle 602 at the point in time T4, based on the seventh moving body information DAT_7. The first processing circuitry 101 of the processing device 100 calculates the predictive moving body information based on the moving body information and the calculation data CAL.

As shown in FIG. 3, enclosed by a long-dash double-short-dash line, the processing device 100 calculates the first predictive moving body information PRE_1 based on the first moving body information DAT_1 and the seventh moving body information DAT_7 at the point in time T0. At the point in time T1, the processing device 100 calculates the second predictive moving body information PRE_2 based on the second moving body information DAT_2 and the first calculation data CAL_1. At the point in time T2, the processing device 100 calculates the third predictive moving body information PRE_3 based on the third moving body information DAT_3 and the second calculation data CAL_2. At the point in time T3, the processing device 100 calculates the fourth predictive moving body information PRE_4 based on the fourth moving body information DAT_4 and the third calculation data CAL_3. At the point in time T4, the processing device 100 calculates the fifth predictive moving body information PRE_5 based on the fifth moving body information DAT_5 and the fourth calculation data CAL_4. At the point in time T5, the processing device 100 calculates the sixth predictive moving body information PRE_6 based on the sixth moving body information DAT_6 and the eighth moving body information DAT_8.

When the update cycle at which the information processing system 10 updates the predictive moving body information is relatively short, the amount of the predictive moving body information to be updated by the information processing system 10 per unit time increases. That is, when the prescribed update cycle, at which the information processing system 10 updates the predictive moving body information, is relatively short, the processing load on the information processing system 10 increases. In this regard, the information processing system 10 determines an appropriate update cycle of the predictive moving body information for each moving body 800 by executing the following processes.

### Processes Executed by Information Processing System 10

Hereinafter, with reference to FIGS. 4 to 8, a flow of processes in which the information processing system 10 determines the update cycle at which the predictive moving body information is updated will be described.

FIG. 4 is a flowchart showing a flow of a series of processes executed by the information processing system 10. The information processing system 10 repeatedly executes this series of processes.

### Acquisition of Moving Body Information

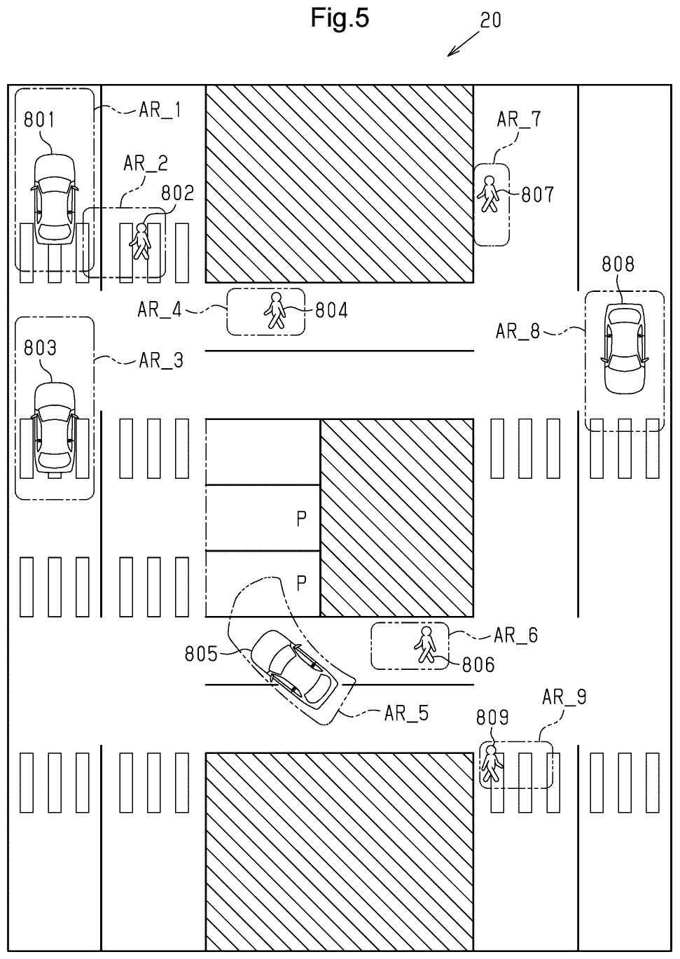

As shown in FIG. 4, when the series of processes is started, the information processing system 10 first acquires the moving body information in an update field 20 in step S10. Specifically, the communication device 300 acquires the moving body information in the update field 20 shown in FIG. 5 via the third communication circuitry 303. The moving body information acquired by the information processing system 10 includes location information of each moving body 800, a moving speed V of each moving body 800, a traveling direction of each moving body 800, and a type of each moving body 800.

FIG. 5 illustrates nine moving bodies 800, which are referred to respectively as a first moving body 801, a second moving body 802, a third moving body 803, a fourth moving body 804, a fifth moving body 805, a sixth moving body 806, a seventh moving body 807, an eighth moving body 808, and a ninth moving body 809. The first moving body 801, the third moving body 803, the fifth moving body 805, and the eighth moving body 808 are vehicles 600. The second moving body 802, the fourth moving body 804, the sixth moving body 806, the seventh moving body 807, and the ninth moving body 809 are pedestrians 700. The information processing system 10 acquires the moving body information of multiple moving bodies 800 in the update field 20 from multiple sensors. After acquiring the moving body information in the update field 20, the communication device 300 advances the process to step S11.

### Division of Update Field 20

In step S11, the processing device 100 of the information processing system 10 acquires the moving body information of each moving body 800 from the communication device 300. In step S11, the processing device 100 establishes a zone for each moving body 800 based on the location information, the moving speed V, and the traveling direction of each moving body 800. Specifically, the processing device 100 establishes multiple zones within the update field 20, corresponding to each moving body 800, such that only one moving body 800 is present within each zone. The range of the zone established for each moving body 800 encompasses the predicted range within which the moving body 800 is expected to be located.

As shown in FIG. 5, the processing device 100 establishes a first zone AR_1 for the first moving body 801. The processing device 100 establishes a second zone AR_2 for the second moving body 802. The processing device 100 establishes a third zone AR_3 for the third moving body 803. The processing device 100 establishes a fourth zone AR 4 for the fourth moving body 804. The processing device 100 establishes a fifth zone AR_5 for the fifth moving body 805. The processing device 100 establishes a sixth zone AR 6 for the sixth moving body 806. The processing device 100 establishes a seventh zone AR_7 for the seventh moving body 807. The processing device 100 establishes an eighth zone AR_8 for the eighth moving body 808. The processing device 100 establishes a ninth zone AR_9 with respect to the ninth moving body 809.

The processing device 100 determines the size of the zone to be established for each moving body 800 according to the moving speed V of the moving body 800 acquired from the communication device 300. Specifically, the processing device 100 narrows the zone assigned to each moving body 800 as the moving speed V of the moving body 800 decreases.

As shown in FIG. 7, the moving speed V of the first moving body 801 is 50 kilometers per hour. The moving speed V of the eighth moving body 808 is 20 kilometers per hour. Accordingly, as shown in FIG. 5, the processing device 100 sets the eighth zone AR_8 established for the eighth moving body 808 to be narrower than the first zone AR_1 established for the first moving body 801.

The processing device 100 may change the range of the zone established for each moving body 800 according to the type of the moving body 800. As illustrated in FIG. 5, the processing device 100 sets zones established for the second moving body 802, the fourth moving body 804, the sixth moving body 806, the seventh moving body 807, and the ninth moving body 809, which are pedestrians 700, to be narrower than zones established for the first moving body 801, the third moving body 803, the fifth moving body 805, and the eighth moving body 808, which are vehicles 600.

The processing device 100 calculates a predicted path based on the acquired information on the traveling direction of each moving body 800. The processing device 100 establishes a zone such that the zone is wider on the side on which the predicted path of the moving body 800 extends. For example, the predicted path of the fifth moving body 805 extends forward and rightward from the fifth moving body 805. The processing device 100 establishes the fifth zone AR_5 for the fifth moving body 805 such that the fifth zone AR_5 is wider on the side on which the predicted path extends. The centroid of the fifth zone AR_5 established for the fifth moving body 805 is located on the side on which the predicted path of the fifth moving body 805 extends with respect to the center of the fifth moving body 805.

The processing device 100 may omit calculating the predictive moving body information for the moving body 800 in areas of the real world where the moving bodies 800 are assumed to be unable to enter. The processing device 100 may omit establishing zones for the moving bodies 800 in ranges where the moving bodies 800 are assumed to be unable to enter. As shown in FIG. 5, the processing device 100 establishes the zone for each moving body 800 such that the zone does not overlap with the shaded regions, which correspond to zones occupied by buildings within the update field 20.

### Allocation of Update Cycle Labels

After establishing zones in which the predictive moving body information is updated for the respective moving bodies 800, the processing device 100 allocates an update cycle label to the zone established for each moving body 800 based on the moving speed V of the moving body 800.

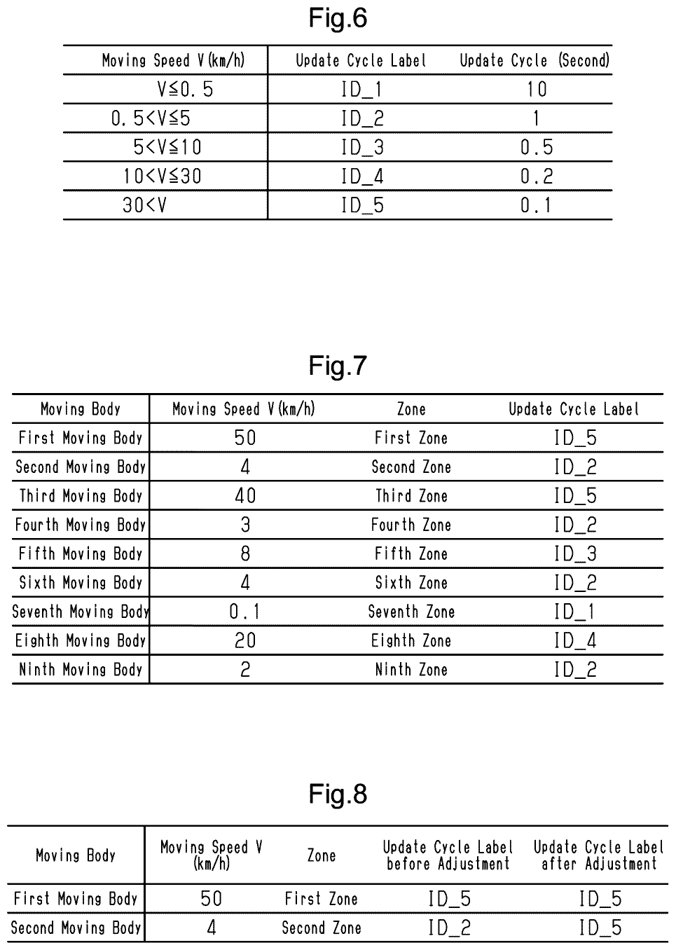

As illustrated in FIG. 6, the processing device 100 allocates ID_1 as an update cycle label to a moving body 800 with a moving speed V of 0.5 kilometers per hour or less. The update cycle of the predictive moving body information of the moving body 800 to which ID_1 is allocated is set to 10 seconds. The processing device 100 allocates ID_2 as an update cycle label to a moving body 800 with a moving speed V greater than 0.5 kilometers per hour and up to 5 kilometers per hour. The update cycle of the predictive moving body information of the moving body 800 to which ID_2 is allocated is set to 1 second. The processing device 100 allocates ID_3 as an update cycle label to a moving body 800 with a moving speed V greater than 5 kilometers per hour and up to 10 kilometers per hour. The update cycle of the predictive moving body information of the moving body 800 to which ID_3 is allocated is set to 0.5 seconds. The processing device 100 allocates ID_4 as an update cycle label to a moving body 800 with a moving speed V greater than 10 kilometers per hour and up to 30 kilometers per hour. The update cycle of the predictive moving body information of the moving body 800 to which ID_4 is allocated is set to 0.2 seconds. The processing device 100 allocates ID_5 as an update cycle label to a moving body 800 with a moving speed V greater than 30 kilometers per hour. The update cycle of the predictive moving body information of the moving body 800 to which ID_5 is allocated is set to 0.1 seconds.

As shown in FIG. 7, the moving speed V of the first moving body 801 is 50 kilometers per hour. Accordingly, the update cycle label of the first zone AR_1 established for the first moving body 801 is ID_5. The moving speed V of the second moving body 802 is 4 kilometers per hour. Accordingly, the update cycle label of the second zone AR_2 established for the second moving body 802 is ID_2. The moving speed V of the third moving body 803 is 40 kilometers per hour. Accordingly, the update cycle label of the third zone AR_3 established for the third moving body 803 is ID_5. The moving speed V of the fourth moving body 804 is 3 kilometers per hour. Accordingly, the update cycle label of the fourth zone AR 4 established for the fourth moving body 804 is ID_2. The moving speed V of the fifth moving body 805 is 8 kilometers per hour. Accordingly, the update cycle label of the fifth zone AR_5 established for the fifth moving body 805 is ID_3. The moving speed V of the sixth moving body 806 is 4 kilometers per hour. Accordingly, the update cycle label of the sixth zone AR 6 established for the sixth moving body 806 is ID_2. The moving speed V of the seventh moving body 807 is 0.1 kilometers per hour. Accordingly, the update cycle label of the seventh zone AR_7 established for the seventh moving body 807 is ID_1. The moving speed V of the eighth moving body 808 is 20 kilometers per hour. Accordingly, the update cycle label of the eighth zone AR_8 established for the eighth moving body 808 is ID_4. The moving speed V of the ninth moving body 809 is 2 kilometers per hour. Accordingly, the update cycle label of the ninth zone AR_9 established for the ninth moving body 809 is ID_2.

After allocating the update cycle labels to the zones established for the respective moving bodies 800 based on the moving speeds V of the moving bodies 800, the processing device 100 advances the process to step S13.

### Adjustment of Update Cycles Assigned to the Zones

In step S13, the processing device 100 adjusts the update cycle of the predictive moving body information determined for each zone in step S11. Specifically, when a part of a zone with a relatively short update cycle and a part of a zone with a relatively long update cycle overlap with each other, the processing device 100 changes the update cycle of the zone with a relatively long update cycle to the update cycle of the zone with a relatively short update cycle.

As shown in FIG. 5, in the update field 20, a part of the first zone AR_1 and a part of the second zone AR_2 overlap with each other. Accordingly, the processing device 100 adjusts the update cycles such that the update cycle of the first zone AR_1 and the update cycle of the second zone AR_2 are the same.

As shown in FIG. 8, the moving speed V of the first moving body 801 is 50 kilometers per hour. The moving speed V of the second moving body 802 is 4 kilometers per hour. The update cycle label of the first moving body 801 is ID_5. The update cycle label of the second moving body 802 is ID_2. In the process of step S13, the processing device 100 changes the update cycle label of the second zone AR_2 to ID_5 in order to change the update cycle of the second zone AR_2 to the update cycle of the first zone AR_1. After adjusting the update cycles, the processing device 100 advances the process to step S14.

### Update of Predictive Moving Body Information for Each Moving Body 800

In step S14, the processing device 100 updates the predictive moving body information for each zone at the update cycle that is set in accordance with the update cycle label allocated to each zone. Thereafter, the processing device 100 transmits the predictive moving body information updated for each zone to the storage device 200.

When the update cycle label allocated to the zone in which the second vehicle 602 illustrated in FIG. 3 is present is ID_3, the update cycle of the predictive moving body information is 0.5 seconds. When the update cycle of the predictive moving body information is 0.5 seconds, the processing device 100 updates the predictive moving body information every 0.5 seconds. The processing device 100 calculates the predictive moving body information of the zone in which the second vehicle 602 is present based on the seventh moving body information DAT_7 at the point in time T0. The processing device 100 transmits the calculated predictive moving body information to the storage device 200. The processing device 100 calculates the predictive moving body information of the zone in which the second vehicle 602 is present based on the eighth moving body information DAT_8 at the point in time T5. The processing device 100 transmits the calculated predictive moving body information to the storage device 200.

During the period from 0.1 seconds to 0.4 seconds, the processing device 100 does not update the predictive moving body information for the zone in which the second vehicle 602 is present. As a result, the update cycle of the predictive moving body information agrees with the acquisition cycle of the moving body information. Consequently, the processing device 100 does not calculate the first calculation data CAL_1, the second calculation data CAL_2, the third calculation data CAL_3, and the fourth calculation data CAL_4.

After executing the process of step S14, the processing device 100 ends the series of processes.

### Calculation of Predictive Moving Body Information of Update Field 20

The second processing circuitry 201 of the storage device 200 generates the predictive moving body information of the entire update field 20 based on the predictive moving body information of each zone acquired from the processing device 100. The second processing circuitry 201 of the storage device 200 stores the predictive moving body information of the entire update field 20 in the second storage circuitry 202.

### Operation of the Present Embodiment

The longer the update cycle of predictive moving body information is, the lower the processing load on the information processing system 10 becomes. According to the above-described configuration, the processing load on the information processing system 10 is reduced compared to a case in which the entire update field 20 is continuously updated at the same cycle.

### Advantages of the Present Embodiment

(1) The information processing system 10 can continuously update the predictive moving body information with a reduced processing load.
(2) The processing device 100 of the information processing system 10 allocates one zone to each moving body 800. The range of the zone established for each moving body 800 encompasses the predicted range within which the moving body 800 is expected to be located. This configuration allows the processing device 100 to change the update cycle of the predictive moving body information for each moving body 800. The information processing system 10 can reflect real-world moving body information into predictive moving body information with a reduced processing load.
(3) The communication device 300 of the information processing system 10 acquires the moving speed V of each moving body 800 as the moving body information. The processing device 100 of the information processing system 10 extends the update cycles for zones containing moving bodies 800 with relatively low moving speeds V. The lower the moving speed V of a moving body 800 is, the smaller the positional changes of the moving body 800 become. Therefore, when the moving speed V of a moving body 800 is relatively low, extending the update cycle for the zone in which the moving body 800 is present results in a small deviation between the real-world traffic environment and the predictive moving body information. A longer update cycle reduces the processing load on the processing device 100 of the information processing system 10. This enables the information processing system 10 to calculate the predictive moving body information with a reduced processing load according to the moving speed V of the moving body 800.
(4) The communication device 300 of the information processing system 10 acquires the moving speed V of each moving body 800 as the moving body information. The processing device 100 of the information processing system 10 narrows zones containing moving bodies 800 with relatively low moving speeds V. When the moving speed V of a moving body 800 is relatively low, the positional changes of the moving body 800 are smaller than those of moving bodies 800 with a relatively high speed. That is, when the moving speed V of a moving body 800 is relatively low, even if the zone assigned to the moving body 800 is narrowed, the moving body 800 will not move beyond the boundaries of that zone. The narrower the zone updated by the processing device 100 of the information processing system 10 is, the lower the processing load on the processing device 100 of the information processing system 10 becomes. This allows the information processing system 10 to reduce the processing load in accordance with the moving speed V of the moving body 800 in the real-world traffic environment.
(5) The processing device 100 of the information processing system 10 acquires information on the traveling direction of each moving body 800 as the moving body information. Based on the moving body information, the processing device 100 calculates a predicted path for each moving body 800. The processing device 100 establishes the zone of the moving body 800 such that the centroid of the zone is positioned on the side on which the predicted path extends with respect to the center of the moving body 800. This configuration allows the processing device 100 of the information processing system 10 to update the predictive moving body information in the direction of travel of the moving body 800 without imposing an excessive processing load.
(6) When providing traffic services based on predictive moving body information, it may be necessary to determine the distances between multiple moving bodies 800. However, if the update cycles of the predictive moving body information differ between moving bodies 800, accurately determining the distances between the moving bodies 800 is difficult. When a zone with a relatively short update cycle overlaps at least partially with a zone with a relatively long update cycle, the processing device 100 of the information processing system 10 aligns the update cycles by setting both zones to the shorter cycle. As a result, the update cycles of the predictive moving body information for the multiple moving bodies 800 located close to each other agree with each other. This allows the information processing system 10 to accurately reflect the positional relationships between the moving bodies 800 located near each other into the predictive moving body information.
(7) In the real world, there are areas where the vehicles 600 cannot enter, such as locations occupied by buildings. The processing device 100 of the information processing system 10 does not establish zones in locations where the vehicles 600 cannot enter. This configuration reduces the processing load on the processing device 100 of the information processing system 10.
(8) When the update cycle of the predictive moving body information is different from the acquisition cycle of the moving body information, the processing device 100 needs to calculate the calculation data CAL based on the moving body information. When the processing device 100 of the information processing system 10 calculates the calculation data CAL, a processing load due to the calculation of the calculation data CAL is applied to the processing device 100. The processing device 100 can match the update cycle of the predictive moving body information with the acquisition cycle of the moving body information by adjusting the update cycle of the predictive moving body information. In this case, the processing device 100 does not need to calculate calculation data CAL. The processing device 100 does not calculate the calculation data CAL when the calculation data CAL is not necessary. Thus, the processing load on the processing device 100 is reduced compared to a case in which the calculation data CAL is always calculated.
(9) The information processing method executed by the information processing system 10 includes a step (step S10) in which the communication device 300 acquires moving body information, which indicates the positions of multiple moving bodies 800 in the real world. The information processing method executed by the information processing system 10 also includes a step (step S11) in which the processing device 100 sets the update cycle of predictive moving body information of at least one of multiple zones to be longer than the update cycles of predictive moving body information of other zones. The information processing method executed by the information processing system 10 includes a step (step S14) in which the processing device 100 acquires, at a prescribed cycle, predictive moving body information, which is information indicating the position of each of the multiple moving bodies 800 after the point in time at which the moving body information is acquired, based on the moving body information. The longer the update cycle of predictive moving body information is, the lower the processing load on the information processing system 10 becomes. The execution of this information processing method reduces the processing load on the information processing system 10 as compared to a case in which the entire update field 20 is continuously updated at the same cycle. The information processing system 10 can continuously update the predictive moving body information with a reduced processing load.
(10) The first storage circuitry 102 of the processing device 100 of the information processing system 10 stores an information processing program that causes the first processing circuitry 101 of the processing device 100 to execute processes. The information processing program includes causes the first processing circuitry 101 of the processing device 100 to set the update cycle of predictive moving body information in at least one of multiple zones to be longer than the update cycles of predictive moving body information in other zones. The longer the update cycle of predictive moving body information is, the lower the processing load on the information processing system 10 becomes. The above-described information processing program reduces the processing load on the information processing system 10 compared to a case in which the entire update field 20 is continuously updated at the same cycle. The information processing system 10 can continuously update the predictive moving body information with a reduced processing load.

### MODIFICATIONS

The above-described embodiment may be modified as follows. The above-described embodiment and the following modifications can be combined as long as the combined modifications remain technically consistent with each other.

The processing device 100 of the information processing system 10 may establish a zone in which a moving body 800 is present and a zone in which no moving body 800 is present in the update field 20. In this case, the processing device 100 sets the update cycle of the predictive moving body information in the zone in which no moving body 800 is present to be longer than the update cycle of the predictive moving body information in the zone in which a moving body 800 is present. The real-world traffic environment in a zone in which no moving body 800 is present is less likely to change compared to a zone in which a moving body 800 is present. Therefore, even if the update cycle for a zone in which no moving body 800 is present is extended, a deviation between the real-world traffic environment and the predictive moving body information is unlikely to occur. Accordingly, the information processing system 10 can continuously update the predictive moving body information with reduced processing load without causing a large deviation between the real-world traffic environment and the predictive moving body information.

The processing device 100 of the information processing system 10 may set multiple zones in the update field 20 so that multiple moving bodies 800 are present in one zone. For example, in FIG. 5, one zone in which both the first moving body 801 and the third moving body 803 are present may be established.

The processing device 100 of the information processing system 10 may define a predicted range within which a specific moving body 800 is expected to be present as a zone in which the specific moving body 800 is present. If another moving body 800 is present and located near the specific moving body 800, the processing device 100 of the information processing system 10 may expand the zone in which the specific moving body 800 is present beyond the range within which the specific moving body 800 is expected to be present. For example, the processing device 100 may expand the zone in which the specific moving body 800 is present so that it overlaps with a zone in which another nearby moving body 800 is present. Accordingly, the processing device 100 can adjust the update cycle of the zone in which the specific moving body 800 is present and the update cycle of the zone in which another nearby moving body 800 is present on condition that these zones overlap with each other. The processing device 100 may also expand the zone in which a specific moving body 800 is present to a range that does not overlap with a zone in which another nearby moving body 800 is present. In some cases, the update cycle for a zone in which no moving body 800 is present is set to be longer than the update cycle for a zone in which a moving body 800 is present. By expanding the zone in which the moving body 800 is present, the processing device 100 prevents the creation of a zone with a longer update cycle between the zone in which the moving body 800 is present and a zone in which another nearby moving body 800 is present.

When multiple moving bodies 800 are present in a single update field 20, the processing device 100 of the information processing system 10 may define, in the update field 20, zones with different update cycles based on the moving speeds V of moving bodies 800. For example, the processing device 100 may define a first zone AR_1 and a second zone AR_2 in the update field 20. The first zone AR_1 of the modification is a zone in which no moving body 800 with a moving speed V higher than or equal to a prescribed first moving speed VL_1 is present. The second zone AR_2 of the modification is a zone in which a moving body 800 with a moving speed V higher than or equal to the prescribed first moving speed VL_1 is present. The processing device 100 sets the update cycle for the first zone AR_1 to be longer than the update cycle of the second zone AR_2. This allows the processing device 100 to change the update cycle of the predictive moving body information in accordance with the moving speed V of each moving body 800 with a processing load less than that in a case in which the update cycle labels are allocated to zones established for the respective moving bodies 800 based on the moving speeds V of the moving bodies 800. The processing device 100 of the information processing system 10 may establish three or more zones in which the update cycle is set in advance with reference to the moving speeds V of moving bodies 800 in a single update field 20. For example, the processing device 100 of the information processing system 10 may further establish a third zone AR_3 as a zone in which the update cycle is determined according to the moving speed V of a moving body 800. The third zone AR_3 of the modification is a zone in which a moving body 800 with a moving speed V higher than or equal to a prescribed second moving speed VL_2 is present. If the third zone AR_3 of the modification is established, the processing device 100 defines the second zone AR_2 of the modification as a zone in which a moving body 800 with a moving speed V that is higher than or equal to the prescribed first moving speed VL_1 and is lower than the prescribed second moving speed VL_2 is present. Further, the processing device 100 sets the update cycle for the second zone AR_2 of the modification to be longer than the update cycle of the third zone AR_3 of the modification.

If the update field 20 includes a zone having a longer update cycle than other zones, the processing load on the information processing system 10 is reduced by an amount corresponding to the zone having the longer update cycle, as compared to a case in which the update cycle of the entire update field 20 is the same. Therefore, the processing device 100 of the information processing system 10 may set the length of the update cycle of the predictive moving body information regardless of whether a moving body 800 is present.

The processing device 100 of the information processing system 10 does not necessarily need to change the update cycle for each zone according to the moving speed V of the moving body 800 present in the zone as long as the update cycle of at least one zone is set to be longer than the update cycles of the other zones.

The processing device 100 of the information processing system 10 may establish multiple zones within the update field 20 to include zones in which no moving body 800 is present.

When predictive moving body information can be calculated with sufficient accuracy, the processing device 100 of the information processing system 10 may set update cycles regardless of the moving speeds V of the moving bodies 800.

When predictive moving body information can be calculated with sufficient accuracy, the processing device 100 of the information processing system 10 may determine the size of each zone regardless of the moving speed V of the moving body 800.

When predictive moving body information can be calculated with a sufficient accuracy, the processing device 100 of the information processing system 10 may set the size of each zone regardless of the traveling direction of the moving body 800.

In step S13, the condition for the processing device 100 of the information processing system 10 to adjust the update cycle is not limited to the case in which two different zones overlap with each other. For example, the processing device 100 may adjust the update cycle on condition that the distance between two different zones is shorter than a prescribed distance.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. An information processing system, comprising processing circuitry, the processing circuitry being configured to:
acquire moving body information that indicates a position of each of multiple moving bodies existing in the real world;
acquire, based on the moving body information, predictive moving body information at a prescribed cycle, the predictive moving body information indicating a predictive position of each of the multiple moving bodies after a point in time at which the moving body information is acquired; and
set the cycle for acquiring the predictive moving body information in at least one zone among multiple zones in which the moving bodies are present to be longer than the cycle for acquiring the predictive moving body information in the other zones.

2. The information processing system according to claim 1, wherein the processing circuitry is configured to:
establish a zone in which no moving body is present in addition to the zones in which the moving bodies are present; and
set the cycle for the zone in which no moving body is present to be longer than the cycle for the zones in which the moving bodies are present.

3. The information processing system according to claim 1, wherein
the moving body information includes a moving speed of each of the moving bodies,
the zones include a first zone and a second zone,
the first zone is a zone in which no moving body with a moving speed higher than or equal to a prescribed moving speed is present,
the second zone is a zone in which one or more moving bodies with a moving speed higher than or equal to the prescribed moving speed are present, and
the processing circuitry is configured to set the cycle for the first zone to be longer than the cycle for the second zone.

4. The information processing system according to claim 1, wherein the processing circuitry is configured to allocate one of the zones to each of the moving bodies.

5. The information processing system according to claim 4, wherein
the moving body information includes a moving speed of each of the moving bodies, and
the processing circuitry is configured to extend the cycle for the zone as the moving speed of the corresponding moving body decreases.

6. The information processing system according to claim 4, wherein
the moving body information includes a moving speed of each of the moving bodies, and
the processing circuitry is configured to narrow the zone as the moving speed of the corresponding moving body decreases.

7. The information processing system according to claim 4, wherein
the moving body information includes information on a traveling direction of each of the moving bodies, and
the processing circuitry is configured to
calculate a predicted path for each moving body from the moving body information; and
define each of the zones for the corresponding moving body such that a centroid of the zone in which the moving body is present is positioned on a side on which the predicted path extends with respect to the center of the moving body.

8. The information processing system according to claim 5, wherein the processing circuitry is configured to, when a zone having a relatively short cycle and a zone having a relatively long cycle at least partially overlap with each other, change the cycle for the zone having the relatively long cycle to the cycle of the zone having the relatively short cycle.

9. The information processing system according to claim 6, wherein the processing circuitry is configured to, when a zone having a relatively short cycle and a zone having a relatively long cycle at least partially overlap with each other, change the cycle for the zone having the relatively long cycle to the cycle of the zone having the relatively short cycle.

10. The information processing system according to claim 7, wherein the processing circuitry is configured to, when a zone having a relatively short cycle and a zone having a relatively long cycle at least partially overlap with each other, change the cycle for the zone having the relatively long cycle to the cycle of the zone having the relatively short cycle.

11. An information processing method, comprising:
acquiring moving body information that indicates a position of each of multiple moving bodies existing in the real world;
acquiring, based on the moving body information, predictive moving body information at a prescribed cycle, the predictive moving body information indicating a predictive position of each of the multiple moving bodies after a point in time at which the moving body information is acquired; and
setting the cycle for acquiring the predictive moving body information in at least one zone among multiple zones in which the moving bodies are present to be longer than the cycle for acquiring the predictive moving body information in the other zones.

12. A non-transitory computer readable storage medium storing an information processing program to be executed by processing circuitry included in an information processing system, wherein
the information processing program causes the processing circuitry to set a cycle for acquiring predictive moving body information in at least one zone among multiple zones in which the moving bodies are present to be longer than the cycle for acquiring the predictive moving body information in the other zones, and
the predictive moving body information is acquired based on moving body information that indicates a position of each of multiple moving bodies present in the real world, the predictive moving body information indicating a predictive position of each of the multiple moving bodies after a point in time at which the moving body information is acquired.
